(19) United States
(12) Patent Application Publication
(10) Pub. No.: US 2012/0300168 A1
(43) Pub. Date: Nov. 29, 2012

(54) OPTICALLY TRANSPARENT CONDUCTORS

(75) Inventor: William E. Hoke, Wayland, MA (US)

(73) Assignee: Raytheon Company, Waltham, MA (US)

(21) Appl. No.: 13/113,838

(22) Filed: May 23, 2011

(51) Int. Cl. G02F 1/136; H01L 29/205

(52) U.S. Cl. 349/202; 257/76; 257/E29.091; 257/E33.068

(57) ABSTRACT

An optically transparent electrically conductive structure having: an optically transparent substrate; an optically transparent buffer and barrier layers; a plurality of optically transparent, two-dimensional electron gas (2-DEG) carrier layers disposed on the substrate. A barrier layer is disposed over a corresponding one of the carrier layers. One of the carrier layers comprises: a GaN channel layer and wherein the barrier layer is Al₁₋ₓInₓN or Al_{5y}Ga_{1-6y}In_{y}N where 0.10<x<0.30 and 0.05<y<0.17.

### TECHNICAL FIELD

This disclosure relates generally to optically transparent conductors and more particularly to optically transparent conductors having low strain and very low sheet resistivity.

### BACKGROUND

As is known in the art, many applications require the use of transparent electrical conductors, One such application is in optical beam steering devices such as optical phase arrays (OPAs) such as described in U.S. Pat. No. 5,126,869 entitled “Two-dimensional, phased-array optical beam steerer” inventors Lipchak, et al., issued Jun. 30, 1992 and assigned to the same assignee as the present invention.

One transparent electrical conductor is shown in FIG. 1 to include a transparent substrate, here sapphire, an aluminum nitride (AlN) nucleation layer on the substrate, a gallium nitride (GaN) buffer layer on the nucleation layer, a10 Angstrom thick AlN interlayer on the buffer layer and a 250 Angstrom thick(aluminum gallium nitride) Al_{0.25}Ga_{0.75}N barrier layer on the AlN layer. Two-dimensional electron gas (2-DEG) carriers exist in the lower bandgap GaN layer near the top GaN/AlN interface. Such structure provides a sheet resistivity of about 300 ohm/sq. Due to spontaneous and piezoelectric polarization in the tensile-strained AlGaN barrier layer and AlN interlayer, two-dimensional electron gas (2-DEG) carriers exist in the lower bandgap GaN layer near the top GaN/AlN interface. HEMT material of this structure has been grown with an absorption of only 0.1% (measured at 1 μm wavelength) and a sheet resistance as low as 300 ohm/sq. Low absorption is possible due to the transparency of the substrate (sapphire in this case but other substrates such as spinel are possible) as well as the large bandgaps of the nitride layers. Lower sheet resistances are desirable to improve frequency performance as well as enable new applications. Furthermore improving the robustness of the layer structure is warranted. The current material structure has the following limitations:
1. Both the AlGaN barrier layer and AlN interlayer in FIG. 1 are under significant tensile strain which makes these layers susceptible to cracking that seriously degrades the conductivity.
2. Increasing the composition of the AlGaN layer to increase the conductivity further increases the tensile strain, reducing the robustness of the structure.
3. Stacking AlGaN/AlN/GaN layers to form multiple 2-DEG conducting layers is not possible or highly limited because the tensile strain is magnified.

In applications requiring lower resistivity, the transparent electrical conductors shown in FIGS. 2 and 3 have been used. Here, the Al_{0.25}Ga_{0.75} N barrier layer in FIG. 1 is replaced by an Al_{0.83}In_{0.17}N barrier layer in FIG. 2 and is replaced by an Al₅ₓGa₁₋₆ₓInₓN barrier layer in FIG. 3. Here, in FIG. 2, the ternary Al_{0.83}In_{0.17}N barrier layer lattice matches the GaN buffer layer. Also the AlGaInN quaternary layer with an aluminum content approximately 5 times the indium content also closely lattice matches GaN. Due to a very large spontaneous polarization, the AlInN and AlGaInNHEMT structures have approximately twice the charge density than the present structure in FIG. 1 enabling sheet resistances of 200 ohm/sq. (AlInN reference: H. Behmenburg et al, Phys. Status Solidi C 6, No. S2, S1041-S1044, 2009.AlGaInN reference: T. Lim et al., IEEE Electron Device Letters Vol. 31, 671-673, 2010.)

The near-lattice matched barrier layers significantly minimize the strain issue with the structure shown in FIG. 1. Indeed the barrier layers can be grown under compressive strain by slightly increasing the indium content beyond the lattice match conditions. Another benefit of these structures (FIGS. 2 and 3) is that low sheet resistances are obtained with barrier layers of 100 Å or less compared to 200-250 Å with the structure in FIG. 1 These nearly lattice matched structures provide a sheet resistance of about 200 ohms/sq. In some applications it would be desirable to reduce the sheet resistivity even further.

### SUMMARY

In accordance with the present disclosure, an optically transparent electrically conductive structure is provided. The structure includes: an optically transparent substrate; a plurality of optically transparent barrier layers; a plurality of optically transparent, two-dimensional electron gas (2-DEG) carrier layers disposed on the substrate. Each one of the barrier layers is disposed over a corresponding one of the carrier layers.

In one embodiment, one of the carrier layers comprises: a GaN channel layer and wherein the barrier layer is Al₁₋ₓInₓN or Al_{5y}Ga_{1-6y}In_{y}N where 0.10<x<0.30 and 0.05<y<0.17.

In one embodiment, the structure includes: a nucleation layer disposed on the substrate; an AlN nucleation layer having a thickness of 200-1000 Angstroms thick disposed on the substrate; a first stack of layers disposed on the nucleation layer. The first stack includes: a bottom GaN buffer layer, here having a thickness of 1-2 micrometers and having a two-dimensional electron gas (2-DEG) carrier layer; an AlN interlayer of AlN, here 8-15 Angstroms thick on the buffer layer; and a barrier layer on the AlN interlayer, the barrier layer having a thickness of 50-150 Angstroms and being Al₁₋ₓInₓN or Al_{5y}Ga_{1-6y}In_{y}N layer, where 0.10<x<0.30 and 0.05<y<0.17. The structure includes one or more additional stacks of layers disposed on the first stack of layers. Each one or more additional stacks of layers comprises: a bottom GaN layer, here having a thickness of 50-400 Angstroms and having a two-dimensional electron gas (2-DEG) carrier layer; an AlN interlayer of AlN, here 8-15 Angstroms thick on the buffer layer; and a barrier layer on the AlN interlayer, the barrier layer having a thickness of 50-150 Angstroms and being aluminum indium nitride (Al₁₋ₓInₓN)or aluminum gallium indium nitride (Al_{5y}Ga_{1-6y}In_{y}N) layer, where 0.10<x<0.30 and 0.05<y<0.17.

In one embodiment, a structure is provided having: an optically transparent substrate; an AlN nucleation layer on the substrate; and a first stacked layer disposed on the nucleation layer, the first stacked layer comprising: a GaN buffer layer having: a two-dimensional electron gas (2-DEG) carrier layer near the top surface of the GaN buffer layer. One or more additional stacked layers are disposed on the first stacked layer, each one of the one or more stacked layers comprising: a GaN layer; and a two-dimensional electron gas (2-DEG) carrier layer disposed therein.

In one embodiment, a structure is provided having: a plurality of stacked two-dimensional electron gas (2-DEG) carrier layerstructures, each one of the two-dimensional electron gas (2-DEG) carrier layerstructures comprising: a GaN channel layer, such GaN channel layer having two-dimensional electron gas (2-DEG) carriers therein; an AlN interlayer on the GaN channel layer; and an Al₁₋ₓInₓN or Al_{5y}Ga_{1-6y}In_{y}N layer on the AlN interlayer, where 0.10<x<0.30 and 0.05<y<0.17.

In one embodiment, an optically transparent electrically conductive structure, comprises: an optically transparent substrate; an optically transparent barrier layer disposed over the substrate; a structure disposed over the barrier layer, comprising: a plurality of stacked two-dimensional electron gas (2-DEG) carrier layerstructures, each one of the two-dimensional electron gas (2-DEG) carrier layerstructures comprising: a GaN layer, an AlN interlayer on the GaN channel layer; and an Al₁₋ₓInₓN or Al_{5y}Ga_{1-6y}In_{y}N layer on the AlN interlayer, where 0.10<x<0.30 and 0.05<y<0.17.

In one embodiment, an optical energy beam steerer is provided having a liquid crystal structure; a plurality of electrically isolated, electrical conductors disposed along a surface of the liquid structure, each one of the electrical conductors, comprising: an optically transparent substrate; a pair of optically transparent barrier layers; a pair of optically transparent, two-dimensional electron gas (2-DEG) carrier layers disposed on the substrate; and wherein each one of the barrier layers is disposed above a corresponding one of the carrier layers.

The inventor has recognized that the minimal amount of strain in the structures of FIGS. 2 and 3 now makes possible stacked structures having a plurality of overlaying 2-DEG conducting layers while maintaining optical transparency. Each repeat 2-DEG conducting layer adds another conducting channel layer to drive down the resistivity. Since barrier layers of 100 Å or less can be used, this structure is compact in the vertical direction which facilitates ohmic contact formation.

The near-lattice matched barrier layers significantly minimize the strain issue with the current structure in FIG. 1. Indeed the barrier layers can be grown under compressive strain by slightly increasing the indium content beyond the lattice match conditions. Another benefit of these structures is that low sheet resistances are obtained with barrier layers of 100 Å or less compared to 200-250 Å with the present structure in FIG. 1.

The details of one or more embodiments of the disclosure are set forth in the accompanying drawings and the description below. Other features, objects, and advantages of the disclosure will be apparent from the description and drawings, and from the claims.

### DESCRIPTION OF DRAWINGS

FIG. 1 is a diagram of an optically transparent electrical conductor according to the PRIOR ART;

FIG. 2 is a diagram of an optically transparent electrical conductor according to the PRIOR ART;

FIG. 3 is a diagram of an optically transparent electrical conductor according to the PRIOR ART;

FIG. 4 is a diagram of a beam steerer having transparent electrical conductors according to the disclosure;

FIG. 5 is a diagram of an optically transparent electrical conductor according to the one embodiment of the disclosure; and

FIG. 6 is a diagram of an optically transparent electrical conductor according to another embodiment of the disclosure.

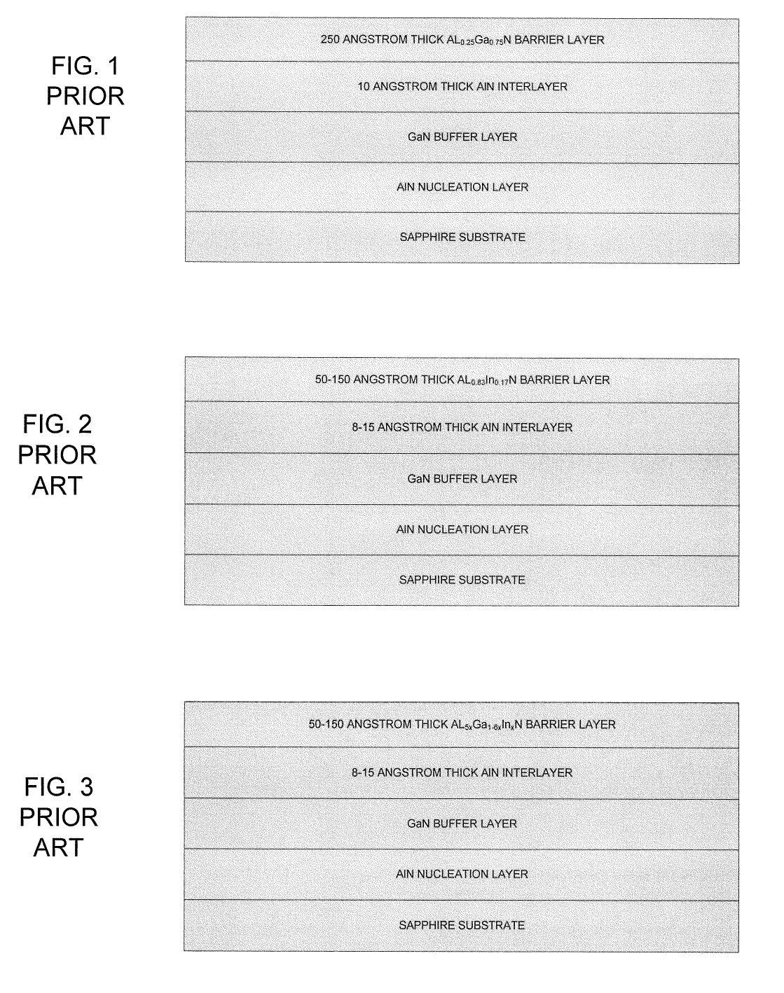

Like reference symbols in the various drawings indicate like elements.

### DETAILED DESCRIPTION

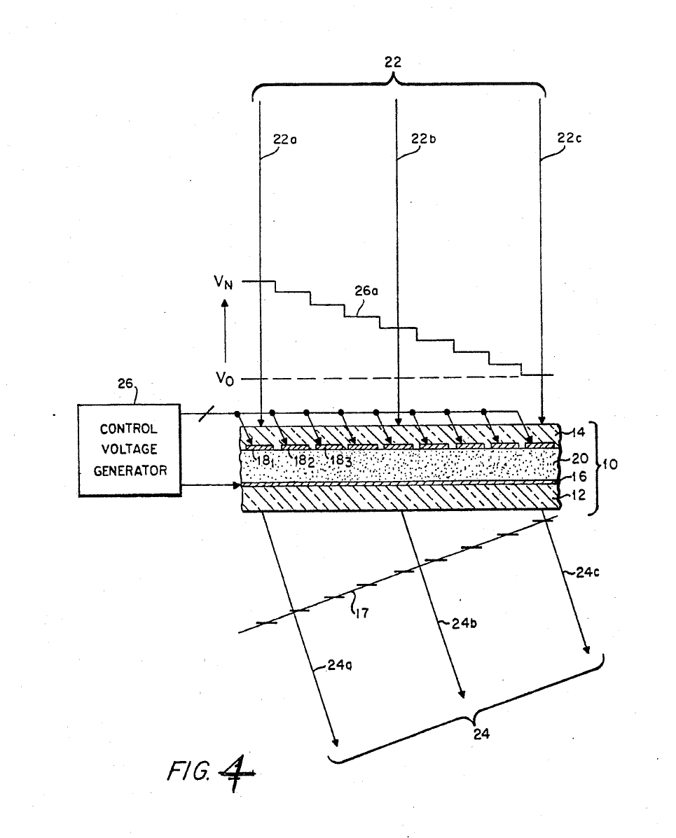

Referring to FIG. 4, there is shown, in diagrammatical cross-sectional view, a liquid crystal beam steering device 10. Device 10 comprises a liquid crystal cell having windows 12 and 14 which are optically transparent at the frequency range of interest. Common electrode 16, affixed to window 12, is electrically conductive and optically transparent. Electrodes 18: 18₁, 18₂, 18₃, . . . , referred to collectively as electrodes 18, affixed to window 14, comprise a plurality of electrically conductive, optically transparent stripes. The space between windows 12 and 14 is filled with a layer of liquid crystal molecules 20, illustratively long, thin, rod-like organic molecules of the so-called “nematic” phase. The liquid crystal devices are the phase shifting elements, which may generally be of the type suggested in Huignard et al. U.S. Pat. No. 4,639,091, issued Jan. 27, 1987, to J.-P. Huignard et al, but which are more specifically similar to the phase shifting elements disclosed and described in U.S. Pat. No. 4,964,701, “Deflector for an Optical Beam,” issued Oct. 23, 1990, to Terry A. Dorschner et al., and assigned to the same assignee as the present invention, which patent ('701) is incorporated herein by reference.

The optical beam phase shifter 10 of FIG. 4 is responsive to a light source and beam forming network (not shown) which provide a polarized, light beam 22, ranging from visible through far infrared. Light beam 22, represented in part by rays 22a-22c, is directed onto window 14 of optical device 10. In the simplified example of FIG. 4, the application of different potentials between common electrode 16 and the individual stripe electrodes 18 from control voltage generator 26 results in differential electric fields in the regions between the individual stripe electrodes 18 and common electrode 16, thereby creating local variations of the refractive index in the liquid crystal layer 20. For ease of understanding, a limited number of stripe electrodes 18 are shown in FIG. 4, whereas, in an actual beam steerer embodying the present invention, there may be many thousands of such stripes.

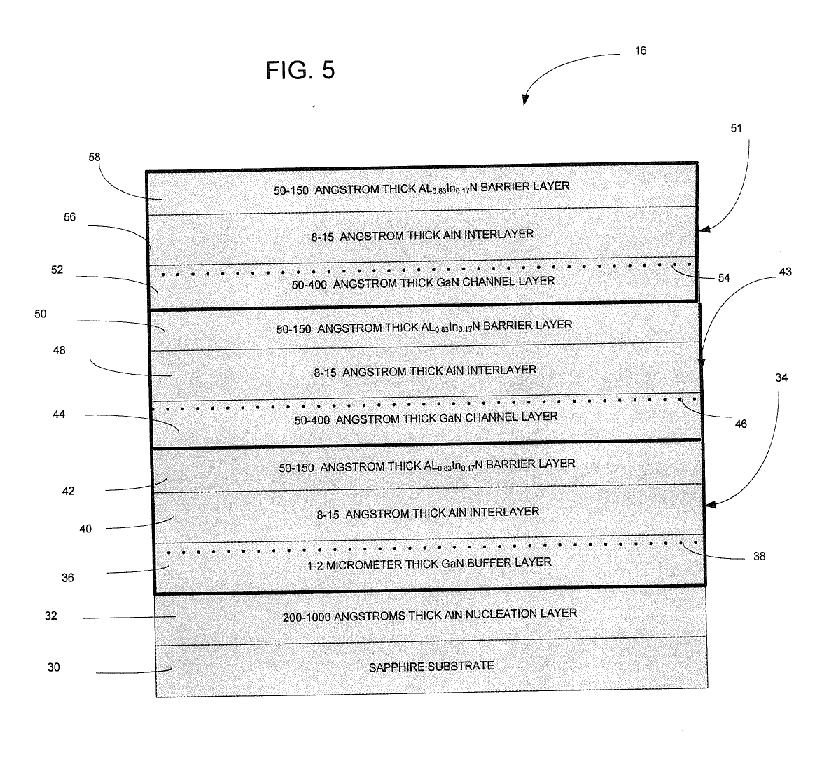

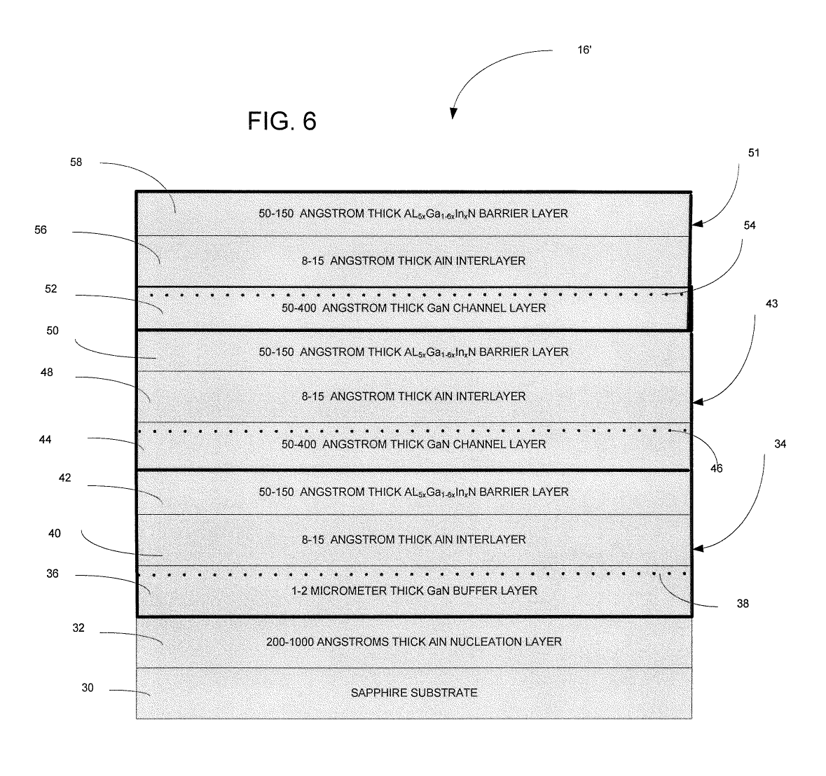

Referring now to FIG. 5, an exemplary of the optically transparent electrical conductors 16, 18, here conductor 16, is shown to include: an optically transparent, single crystal substrate 30, here for example, sapphire, spinel, AlN. Disposed on the substrate 30 is a nucleation layer 32, here for example, AlN having a thickness of 200-1000 Angstroms thick. Disposed on the nucleation layer 32 is a stack 34 of layers, such stack 34 having: a bottom GaN buffer layer 36, here having a thickness of 1-2 micrometers and having a two-dimensional electron gas (2-DEG) carrier layer 38 therein indicated by the dotted line, an AlN interlayer of AlN 40, here 8-15 Angstroms thick on the buffer layer 36; and a barrier layer 42 having a thickness of 50-150 Angstroms on the AlN interlayer 40. The barrier layer 42 is here an Al₁₋ₓInₓN layer as shown in FIG. 5 or Al_{5y}Ga_{1-6y}In_{y}N layer as shown in FIG. 6, where 0.10<x<0.30 and 0.05<y<0.17.

Disposed on the stack 34 of layers is one or more additional, here two additional stacks 43, 51 of layers, each one of the stacks 43, 51 of layers being the same as the bottom stack 34 of layers except that here the GaN channel layer in the additional stack or stacks of layers has a thickness of 50-400 Angstroms.

Thus, referring to FIG. 5, stack 43 has a bottom GaN channel layer 44, here having a thickness of 50-400 angstroms and having a two-dimensional electron gas (2-DEG) carrier layer 46 therein indicated by the dotted line, an AlN interlayer 48 of AlN, here 8-15 Angstroms thick on the GaN channel layer 44; and a barrier layer 50 having a thickness of 50-150 Angstroms on the AlN interlayer 48. The barrier layer 50 is here an Al₁₋ₓInₓN layer as shown in FIG. 5 or Al_{5y}Ga_{1-6y}In_{y}N layer indicated as 50′ in FIG. 6.

Likewise, stack 51 has a bottom GaN channel layer 52, here having a thickness of 50-400 angstroms and having a two-dimensional electron gas (2-DEG) carrier layer 54 therein indicated by the dotted line, an AlN interlayer 56 of AlN, here 8-15 Angstroms thick on the GaN channel layer 52; and a barrier layer 58 having a thickness of 50-150 Angstroms on the AlN interlayer 56. The barrier layer 58 is here an Al₁₋ₓInₓN layer as shown in FIG. 5 or Al_{5y}Ga_{1-6y}In_{y}N layer indicated as 58′ in FIG. 6.

A number of embodiments of the disclosure have been described. Nevertheless, it will be understood that various modifications may be made without departing from the spirit and scope of the disclosure. Accordingly, other embodiments are within the scope of the following claims.

What is claimed is:

1. An optically transparent electrically conductive structure, comprising:
an optically transparent substrate;
a plurality of optically transparent barrier layers;
a plurality of optically transparent, two-dimensional electron gas (2-DEG) carrier layers disposed on the substrate; and
wherein each one of the barrier layers is disposed over a corresponding one of the carrier layers.

2. The structure recited in claim 1 wherein each one of the carrier layers comprises: a GaN channel layer and wherein the barrier layer is Al₁₋ₓInₓNor Al_{5y}Ga_{1-6y}In_{y}N where 0.10<x<0.30 and 0.05<y<0.17.

3. The structure recited in claim 2 wherein:
a nucleation layer disposed on the substrate;
an AlN layer having a thickness of 200-1000 Angstroms thick disposed on the substrate; and
a first stack of layers disposed on the nucleation layer, such stack having:
a bottom GaN buffer layer, here having a thickness of 1-2 micrometers and having a two-dimensional electron gas (2-DEG) carrier layer;
an AlN interlayer of AlN, here 8-15 Angstroms thick on the buffer layer; and
a barrier layer on the AlN interlayer, the barrier layer having a thickness of 50-150 Angstroms and being Al₁₋ₓInₓNor Al_{5y}Ga_{1-6y}In_{y}N layer, where 0.10<x<0.30 and 0.05<y<0.17; and
one or more additional stacks of layers disposed on the first stack of layers, each one or more additional stacks of layers comprising:
a bottom GaN channel layer, here having a thickness of 50-400 Angstroms and having a two-dimensional electron gas (2-DEG) carrier layer;
an AlN interlayer of AlN, here 8-15 Angstroms thick on the buffer layer; and
a barrier layer on the AlN interlayer, the barrier layer having a thickness of 50-150 Angstroms and being Al₁₋ₓInₓN or Al_{5y}Ga_{1-6y}In_{y}N layer, where 0.10<x<0.30 and 0.05<y<0.17.

4. A structure, comprising:
an optically transparent substrate;
an MN nucleation layer on the substrate;
a first stacked layer disposed on the nucleation layer, the first stacked layer comprising:
a GaN buffer layer; and
a two-dimensional electron gas (2-DEG) carrier layer disposed therein the buffer layer;
one or more additional stacked layers disposed on the first stacked layer, each one of the one or more stacked layers comprising:
a GaN channel layer; and
a two-dimensional electron gas (2-DEG) carrier layer disposed in the channel layer.

5. A structure, comprising:
a plurality of stacked two-dimensional electron gas (2-DEG) carrier layers, each one of the two-dimensional electron gas (2-DEG) carrier layers comprising:
a GaN channel layer, such GaN channel layer having two-dimensional electron gas (2-DEG) carriers therein;
an AlN interlayer on the GaN channel layer; and
an Al₁₋ₓInₓN or Al_{5y}Ga_{1-6y}In_{y}N layer on the AlN interlayer, 0.10<x<0.30 and 0.05<y<0.17.

6. An optically transparent electrically conductive structure, comprising:
an optically transparent substrate;
an optically transparent barrier layer disposed over the substrate;
a structure disposed over the barrier layer, comprising:
a plurality of stacked two-dimensional electron gas (2-DEG) carriers, each one of the two-dimensional electron gas (2-DEG) carrier layers comprising:
an AlN interlayer on the GaN channel layer; and
an Al₁₋ₓInₓN or Al_{5y}Ga_{1-6y}In_{y}N layer on the AlN interlayer, 0.10<x<0.30 and 0.05<y<0.17.

7. An optical energy beam steerer, comprising:
a liquid crystal structure;
a plurality of electrically isolated, electrical conductors disposed along a surface of the liquid structure, each one of the electrical conductors, comprising:
an optically transparent substrate;
a plurality of optically transparent barrier layers;
a plurality of optically transparent, two-dimensional electron gas (2-DEG) carrier layers disposed on the substrate; and
wherein each one of the barrier layers is disposed over a corresponding one of the carrier layers.

8. The beam steerer recited in claim 7 wherein each one of the carrier layers comprises: a GaN channel layer and wherein the barrier layers are Al₁₋ₓInₓN or Al_{5y}Ga_{1-6y}In_{y}N where 0.10<x<0.30 and 0.05<y<0.17.

9. An optical energy beam steerer, comprising:
a liquid crystal structure;
a plurality of electrically isolated, electrical conductors disposed along a surface of the liquid structure, each one of the electrical conductors, comprising:
an AlN layer having a thickness of 200-1000 Angstroms thick disposed on the liquid crystal structure; and
a first stack of layers disposed on the AlN layer, such stack having:
a bottom GaN buffer layer, here having a thickness of 1-2 micrometers and having a two-dimensional electron gas (2-DEG) carrier layer;
an AlN interlayer of AlN, here 8-15 Angstroms thick on the buffer layer; and
a barrier layer on the AlN interlayer, the barrier layer having a thickness of 50-150 Angstroms and being Al₁₋ₓInₓN or Al_{5y}Ga_{1-6y}In_{y}N layer, where 0.10<x<0.30 and 0.05<y<0.17; and
one or more additional stacks of layers disposed on the first stack of layers, each one or more additional stacks of layers comprising:
a bottom GaN channel layer, here having a thickness of 50-400 Angstroms and having a two-dimensional electron gas (2-DEG) carrier layer;
an AlN interlayer of AlN, here 8-15 Angstroms thick on the buffer layer; and
a barrier layer on the AlN interlayer, the barrier layer having a thickness of 50-150 Angstroms and being Al₁₋ₓInₓN or Al_{5y}Ga_{1-6y}In_{y}N layer, where 0.10<x<0.30 and 0.05<y<0.17.
